(19) United States
(12) Patent Application Publication
(10) Pub. No.: US 2006/0216965 A1
(43) Pub. Date: Sep. 28, 2006

(54) Receiving box

(75) Inventors: Makoto Yamanashi, Makinohara-shi (JP); Keiichi Ishii, Makinohara-shi (JP); Naoto Taguchi, Makinohara-shi (JP)

Correspondence Address: SUGHRUE MION, PLLC, 2100 PENNSYLVANIA AVENUE, N.W., SUITE 800, WASHINGTON, DC, 20037, US

(73) Assignee: YAZAKI CORPORATION

(21) Appl. No.: 11/385,865

(22) Filed: Mar. 22, 2006

(30) Foreign Application Priority Data
Mar. 23, 2005 (JP) P2005-083952

(51) Int. Cl. H05K 1/00

(52) U.S. Cl. 439/76.1

(57) ABSTRACT

A receiving box for receiving a plurality of electric circuit boards having board connectors respectively, includes a receiving box body that is configured to receive the electric circuit boards therein, and has an opening for exposing the board connectors therethrough, a lid member that has a connector for connecting to a mating connector of a wire harness, and a connection circuit member that has a plurality of connectors for electrically connecting to the board connectors of the electric circuit boards, and is mounted on the lid member so as to electrically connect the connector of the lid member to the connectors of the connection circuit member. When the lid member is attached to the receiving box body to cover the opening in the receiving box body, the connectors of the connection circuit member are collectively fitted to the board connectors respectively.

### BACKGROUND OF THE INVENTION

This invention relates to a receiving box for receiving a plurality of electric circuit boards in a stacked manner.

Many on-vehicle electrical equipments and electronic control units (hereinafter often referred to as “ECU”) for controlling these electrical equipments are mounted in a dispersed manner on various portions of a vehicle such as an automobile. Generally, each ECU is mounted on an ECU board (or electronic control board), and these ECU boards are received within separate receiving boxes, respectively, and these receiving boxes are mounted in a dispersed manner on the various portions of the vehicle.

In recent years, with a high value-added design of vehicles such as automobiles, there is a tendency for the number of ECUs to increase, and therefore an installation space for the ECUs has increased, and also the number of wire harnesses (connecting electrical equipments to the ECUs), as well as the number of connectors used for these connections, have much increased. Therefore, connector fitting-operations and the installation of the wire harnesses have become complicated, and besides an installation space for the wire harnesses has increased. Thus, the space, required for mounting the ECUs has been more and more increasing with the high value-added design of the vehicles.

On the other hand, it has been strongly required to increase a passenger room space so that the comfortable passenger room space can be provided. Therefore, it has now been of urgent necessity to solve the mutually contradictory problems, that is, to secure the passenger room space and to secure the installation space for the wire harnesses.

There is known an ECU-centralized receiving box in which a plurality of ECU boards are received in a stacked manner within a receiving box body, 5 thereby reducing an ECU-mounting space (see, for example, JP-A-2003-304083 (Pages 5 to 6, FIG. 1)). In this ECU-centralized receiving box disclosed in JP-A-2003-304083, the plurality of ECU boards are received in a stacked manner within the receiving box body, and a bus bar is connected to a conductor end portion formed at one end of each ECU board, and the bus bar forms a common circuit for the ECU boards, and the common circuit for the plurality of ECU boards is connected collectively to the ECU boards. A directly-mounted connector is fixed to the other end of each ECU board, and mating connectors, provided respectively at wire harnesses, are fitted respectively to the directly-mounted connectors, so that the ECU boards are electrically connected respectively to electrical equipments mounted on various portions of a vehicle.

In the ECU-centralized receiving box disclosed in JP-A-2003-304083, the plurality of ECU boards are received in the stacked condition in the casing, and the ECU boards are connected by the bus bar, thereby forming the common circuit. Therefore, as compared with the case where ECUs are mounted in a dispersed manner, and are connected by wire harnesses, there is achieved an advantage that the mounting space is reduced. However, each time a circuit pattern of the ECU boards is changed according to a required specification, a new bus bar must be provided so as to meet the required specification.

And besides, a large opening is formed in one side surface of the ECU casing of the ECU-centralized receiving box of JP-A-2003-304083 so that the ECU boards can be inserted into the casing through this opening. Many insertion holes for the insertion of the mating connectors (provided at the wire harnesses) thereinto are formed in an ECU casing lid for covering the opening. Therefore, the ECU-centralized receiving box has a low mechanical strength.

Generally, in many cases, connectors, mounted on ECU boards received within an ECU-centralized receiving box, are located randomly even if the connectors belong to the same installation system, and each time the connectors are connected together, it is required to carry out a cumbersome connector-connecting operation in which the connectors to be connected together are first found, and then are connected together. The number of the connectors increases with the increase of the number of ECU boards received within the ECU-centralized receiving box, and therefore the burden to find out the connectors to be connected together greatly increases. Also, much time and labor are required for the connector-connecting operation, and besides the possibility of erroneous connections increases. Furthermore, the wire harnesses, connected through the connectors, are installed in a complicated manner, and therefore a maintenance operation can not be easily effected, and besides the quality of the product is lowered.

### SUMMARY OF THE INVENTION

This invention has been made in view of the above circumstances, and an object of the invention is to provide an electric circuit board receiving box which can greatly enhance the efficiency of an operation for connecting connectors (i.e., board connectors) of a plurality of electric circuit boards (received in the receiving box in a stacked manner) to mating connectors of wire harnesses, and has a high mechanical strength.

The above object has been achieved by electric circuit board receiving boxes recited in the following Paragraphs (1) and (2).

(1) An electric circuit board receiving box for receiving a plurality of electric circuit boards in a stacked manner, each of the electric circuit boards including a base board having electric circuit patterns formed thereon, and a board connector which is mounted on the base board to extend along one end edge of the base board, and is electrically connected to the electric circuit patterns; characterized in that the electric circuit board receiving box comprises:

a receiving box body which has an opening formed in one side surface thereof, and receives the plurality of electric circuit boards therein in such a manner that the base boards are arranged at intervals, with the board is connectors exposed through the opening;

a lid member on which a connector housing, receiving input/output terminals electrically connectable to a mating connector of a wire harness, is integrally molded; and

a connection circuit member which is fixed to the lid member so as to be interposed between the lid member and the receiving box body, and includes a plurality of connectors fitted respectively to the board connectors to be electrically connected thereto, the plurality of connectors being electrically connected to the input/output terminals; and

the lid member is attached to the receiving box body to cover the opening in the receiving box body in such a manner that the connectors of the connection circuit member are collectively fitted respectively to the board connectors at a time.

(2) An electric circuit board receiving box for receiving a plurality of electric circuit boards in a stacked manner, each of the electric circuit boards including a base board having electric circuit patterns formed thereon, and a board connector which is mounted on the base board to extend along one end edge of the base board, and is electrically connected to the electric circuit patterns; characterized in that the electric circuit board receiving box comprises:

a receiving box body which has an opening formed in one side surface thereof, and receives the plurality of electric circuit boards therein in such a manner that the base boards are arranged at intervals, with the board connectors exposed through the opening;

a lid member on which a connector housing, receiving input/output terminals electrically connectable to a mating connector of a wire harness, is formed; and

a connection circuit member which is fixed to the lid member so as to be interposed between the lid member and the receiving box body, and includes a plurality of connectors fitted respectively to the board connectors to be electrically connected thereto, the connectors being electrically connected to the input/output terminals; and

the connection circuit member includes an integral housing lid on which connector housings, receiving connection terminals of the plurality of connectors, are integrally molded; and

the integral housing lid is attached to the receiving box body to cover the opening in the receiving box body in such a manner that the connectors of the connection circuit member are collectively fitted respectively to the board connectors at a time.

In the electric circuit board receiving box recited in the above Paragraph (1), the lid member is attached to the receiving box body to cover the opening of the receiving box body in such a manner that the plurality of connectors are collectively fitted at a time to the respective board connectors mounted respectively on the plurality of electric circuit boards received in the receiving box body. Therefore, the efficiency of the connecting operation is greatly enhanced. In other words, it is not necessary to carry out a cumbersome connecting operation in which the connectors to be connected together are first found, and then are connected together, and therefore the operation for connecting the connectors together can be easily carried out. And besides, an erroneous connection of the connectors, that is, an erroneous installation, can be positively prevented, and the installation of high reliability is can be effected. Furthermore, the lid member for covering the opening of the receiving box body is molded integrally with the connector housing receiving the input/output terminals for electrical connection to the mating connector of the wire harness, and therefore the mechanical strength of the lid member is high, and the receiving box body is reinforced by the lid member attached thereto.

Similarly, in the electric circuit board receiving box recited in the above Paragraph (2), the integral housing lid of the connection circuit member is attached to the receiving box body to cover the opening of the receiving box body in such a manner that the plurality of connectors of the connection circuit member are collectively fitted at a time to the respective board connectors mounted respectively on the plurality of electric circuit boards received in the receiving box body. Therefore, the efficiency of the connecting operation is greatly enhanced. In other words, it is not necessary to carry out a cumbersome connecting operation in which the connectors to be connected together are first found, and then are connected together, and therefore the operation for connecting the connectors together can be easily carried out. And besides, an erroneous connection of the connectors, that is, an erroneous installation, can be positively prevented, and the installation of high reliability can be effected. Furthermore, the connector housings, each receiving the connection terminals of the connector (which is to be fitted to the board connector to be electrically connected thereto) are molded integrally on the integral housing lid of the connection circuit member, and therefore the mechanical strength of the integral housing lid is high. Therefore, the receiving box body is reinforced by the integral housing lid attached thereto.

According to the present invention, there is also provided a receiving box for receiving a plurality of electric circuit boards having board connectors respectively, comprising:

a receiving box body that is configured to receive the electric circuit boards therein, and has an opening for exposing the board connectors therethrough;

a lid member that has a connector for connecting to a mating connector of a wire harness; and

a connection circuit member that has a plurality of connectors for electrically connecting to the board connectors of the electric circuit boards, and is mounted on the lid member so as to electrically connect the connector of the lid member to the connectors of the connection circuit member,

wherein when the lid member is attached to the receiving box body to cover the opening in the receiving box body, the connectors of the connection circuit member are collectively fitted to the board connectors respectively.

Preferably, the lid member has a first engagement portion. The receiving box body has a second engagement portion that engages to the first engagement portion of the lid member.

Preferably, the connection circuit member is interposed between the lid member and the receiving box body.

Preferably, the electric circuit boards are arranged at intervals in a stacked manner.

According to the present invention, there is also provided a receiving box for receiving a plurality of electric circuit boards having board connectors respectively, comprising:

a receiving box body that is configured to receive the electric circuit boards therein, and has an opening for exposing the board connectors therethrough;

a lid member that has a connector for connecting to a mating connector of a wire harness;

a connection circuit member that has a plurality of connecting terminals for electrically connecting to the board connectors of the electric circuit boards, and is configured to electrically connect the connector of the lid member to the connectors of the connection circuit member; and

a housing lid member that has a plurality of housings for receiving the connecting terminals to form a plurality of connectors of the connection circuit member,

wherein when the lid housing member is attached to the receiving box body to cover the opening in the receiving box body, the connectors of the connection circuit member are collectively fitted to the board connectors respectively.

Preferably, the lid housing member has a first engagement portion.The receiving box body has a second engagement portion that engages to the first engagement portion of the lid housing member.

Preferably, the lid member has a third engagement portion. The lid housing member has a fourth engagement portion that engages to the third engagement portion of the lid member.

Preferably, the connection circuit member is interposed between the lid member and the lid housing member.

Preferably, the electric circuit boards are arranged at intervals in a stacked manner.

In the present invention, there can be provided the electric circuit board receiving box which can greatly enhance the efficiency of the operation for connecting the board connectors of the plurality of electric circuit boards (received in the receiving box in a stacked manner) to the mating connectors of the wire harnesses, and has the high mechanical strength.

The present invention has been briefly described above. Details of the invention will become manifest upon reading the following Section “Best Mode for Carrying Out the Invention” with reference to the accompanying drawings.

### BRIEF DESCRIPTION OF THE DRAWINGS

The above objects and advantages of the present invention will become more apparent by describing in detail preferred exemplary embodiments thereof with reference to the accompanying drawings, wherein:

FIG. 1 is an exploded, perspective view of a first embodiment of an electric circuit board receiving box of the present invention;

FIG. 2 is an exploded, perspective view showing a connection circuit member and a lid member of FIG. 1;

FIG. 3 is a vertical cross-sectional view of the electric circuit board receiving box of FIG. 1 having electric circuit boards received therein;

FIG. 4 is an exploded, perspective view of a modified electric circuit board receiving box;

FIG. 5 is an exploded, perspective view showing a connection circuit member and a lid member of FIG. 4;

FIG. 6 is a vertical cross-sectional view of a second embodiment of an electric circuit board receiving box of the invention;

FIG. 7 is a vertical cross-sectional view of a third embodiment of an electric circuit board receiving box of the invention;

FIG. 8 is a vertical cross-sectional view of a fourth embodiment of an electric circuit board receiving box of the invention;

FIG. 9 is a vertical cross-sectional view of a fifth embodiment of an electric circuit board receiving box of the invention;

FIG. 10 is a vertical cross-sectional view of a sixth embodiment of an electric circuit board receiving box of the invention;

FIG. 11 is a vertical cross-sectional view of a seventh embodiment of an electric circuit board receiving box of the invention;

FIG. 12 is a vertical cross-sectional view of an eighth embodiment of an electric circuit board receiving box of the invention;

FIG. 13 is a vertical cross-sectional view of a ninth embodiment of an electric circuit board receiving box of the invention;

FIG. 14 is a vertical cross-sectional view of a tenth embodiment of an electric circuit board receiving box of the invention;

FIG. 15 is a vertical cross-sectional view of an eleventh embodiment of an electric circuit board receiving box of the invention;

FIG. 16 is a vertical cross-sectional view of a twelfth embodiment of an electric circuit board receiving box of the invention; and

FIG. 17 is a vertical cross-sectional view of a thirteenth embodiment of an electric circuit board receiving box of the invention.

### DETAILED DESCRIPTION OF THE PREFERRED EMBODIMENTS

A preferred embodiment of the present invention will now be described in detail with reference to the drawings.

### First Embodiment

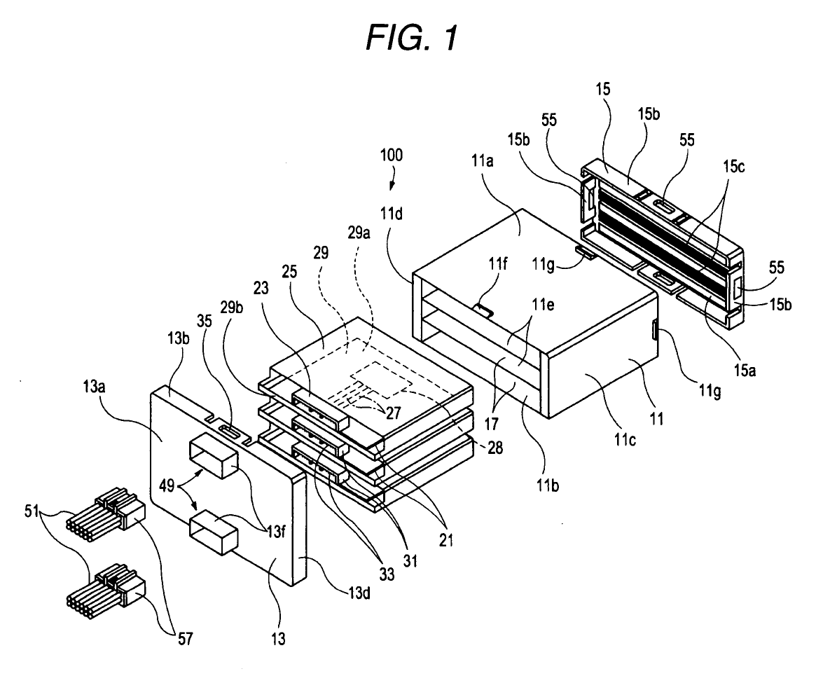

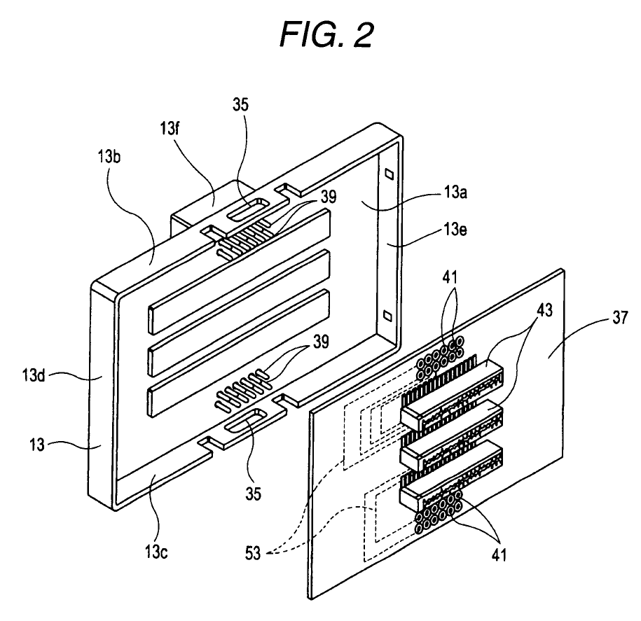

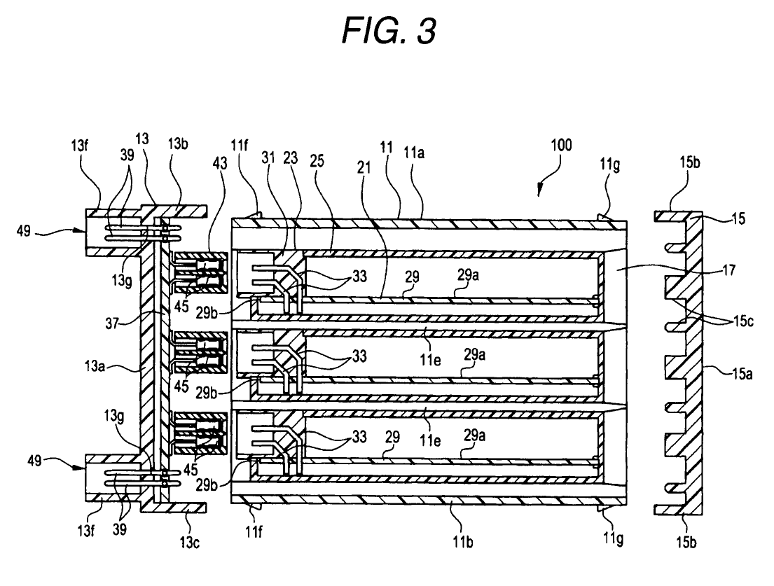

FIG. 1 is an exploded, perspective view of the first embodiment of an electric circuit board receiving box of the invention, FIG. 2 is an exploded, perspective view showing a connection circuit member and a lid member of FIG. 1, and FIG. 3 is a vertical cross-sectional view of the electric circuit board receiving box of FIG. 1 having electric circuit boards received therein.

As shown in FIGS. 1 to 3, the first embodiment of the electric circuit board receiving box 100 of the invention can receive the plurality of electric circuit boards 21 in a stacked manner, and each of the electric circuit boards 21 includes a base board 29 having electric circuit patterns 27 formed thereon, and a board connector 23 which is mounted on the base board 29 to extend along one end edge 29b of this base board 29, and is electrically connected to the electric circuit patterns 27. The electric circuit board receiving box 100 comprises:

a receiving box body 11 which has an opening formed in one side surface thereof, and receives the plurality of electric circuit boards 21 therein in such a manner that the base boards 29 are arranged at intervals, with the board connectors 23 exposed through the opening;

the lid member 13 on which connector housings 13f, each receiving input/output terminals 39 electrically connectable to a mating connector 57 of a wire harness 51, are integrally molded; and

the connection circuit member 37 which is fixed to the lid member 13 so as to be interposed between the lid member 13 and the receiving box body 11, and includes a plurality of connectors 43 fitted respectively to the board connectors 23 to be electrically connected thereto, the connectors 43 being electrically connected to the input/output terminals 39.

The lid member 13 is attached to the receiving box body 11 to cover the opening in the receiving box body 11 in such a manner that the connectors 43 of the connection circuit member 37 are collectively fitted respectively to the board connectors 23 at a time.

The electric circuit board receiving box 100 of this construction will be described below in detail.

The electric circuit board receiving box 100 includes the receiving box 11, the lid member 13, and a rear lid 15. The receiving box body 11 has a generally hollow square pillar-like shape, and has an upper surface 11a, a lower surface 11b, and right and left side walls 11c and 11d continuous with the upper and lower surfaces 11a and 11b. The interior of the receiving box body 11 is partitioned by a plurality of partition walls 11e such that a plurality of board receiving chambers 17 are formed within the receiving box body 11. Each board receiving chamber 17 extends through the receiving box board in a forward-rearward direction, and are open at its front and rear sides to the exterior. The electric circuit boards 21, received respectively in inner cases 25, are received in the board receiving chambers 17, respectively.

Here, the direction of insertion and withdrawal of the board connectors 23 of the electric circuit boards 21 are defined as “the forward-rearward direction”, and a direction perpendicular to this forward-rearward direction and also to a sheet of FIG. 3 is defined as a left-right direction, and a direction perpendicular to the forward-rearward direction and the left-right direction is defined as an upward-downward direction. In the present specification, description will hereafter be made, using these definitions.

Retaining projections 11f of a generally triangular cross-section are formed respectively on generally central portions (in the right-left direction) of the upper and lower surfaces 11a and 11b of the receiving box body 11 at a front end portion thereof, and each of the retaining projections 11f has a slanting surface gradually increasing in height toward the rear end of the receiving box body 11. Retaining projections 11g of a generally triangular cross-section, similar in shape to the retaining projections 11f, are formed respectively on generally central portions (in the right-left direction) of the upper and lower surfaces 11a and 11b and generally central portions (in the upward-downward direction) of the right and left side walls 11c and 11d of the receiving box body 11 at the rear end portion thereof.

Each electric circuit board 21 includes the base board 29 having an electric circuit pattern surface 29a on which the electric circuit patterns 27 (to which an electronic control unit 28 is electrically connected) are formed. The electric circuit board 21 includes at least one board connector 23 which is mounted on the electric circuit pattern surface 29a to extend along the one end edge 29b of the base board 29. The electric circuit boards 21 are received within the inner cases 25, respectively, and are received respectively within the board receiving chambers 17 such that the electric circuit boards 21 are arranged at intervals in a stacked condition. In the first embodiment, the board connector 23 comprises male connection terminals 33, and a female housing 31 receiving the male connection terminals 33, and one end portions of the male connection terminals 33 pass through respective through holes of the base board 29, and are soldered thereto, while the other end portions are bent at a right angle to extend parallel to the base board 29. The board connector 23 is an angle connector of the board directly-mounted type relative to which its mating connector can be inserted and withdrawn in a direction parallel to the electric circuit board 21.

The lid member 13 serves to close the front opening of the receiving box body 11, and this lid member 13 has a box-like shape with a closed bottom, and includes a rectangular plate-like lid body 13, and an upper wall 13b, a lower wall 13c and right and left side walls 13d and 13 which project respectively from four sides of the lid body 13a perpendicularly to this lid body 13a. The hood-like connector housings (female connector housings) 13f, each having through holes 13g (through which the input/output terminals 39 of the connection circuit member 37 (described later) extend, respectively), are formed on and project outwardly from the lid body 13a. Retaining holes 35 for engagement respectively with the retaining projections 11f of the receiving box body 11 are formed respectively through generally central portions (in the right-left direction) of the upper and lower walls 13b and 13c.

As shown in FIG. 2, the connection circuit member 37 is fixed to an inner surface of the lid member 13. The connectors 43, each receiving female connection terminals 45, are mounted on one side (or surface) of the connection circuit member 37 in corresponding relation to the respective board connectors 23 of the electric circuit boards 21. In this embodiment, the connector 43 is of the male type in which the female connection terminals 45 are surface-mounted on the surface of the connection circuit member 37. The input/output terminals 39 are mounted at the other side (or surface) of the connection circuit member 37.

Rear end portions of the input/output terminals 39 are inserted respectively in through holes 41, formed through the circuit connection member 37, and are soldered thereto, while front end portions of these terminals 39 pass respectively through the through holes 13g in the lid member 13, and project into the corresponding connector housings 13f. Namely, each connector housing 13f and the associated input/output terminals 39 jointly form an input/output connector 49 which is fitted to the mating connector 57 of the corresponding wire harness 51. The female connection terminals 45 of the connectors 43 are suitably adjusted or integrated by electric circuit patterns 53 formed on the connection circuit member 37, and are electrically connected to the input/output terminals 39.

The rear lid 15 serves to close the rear openings of the board receiving chambers 17 (that is, the rear opening of the receiving box body 11), and this rear lid 15 has a box-like shape with a closed bottom, and includes a rectangular plate-like lid portion 15a having generally the same size as the rear opening, and a rectangular frame-like side wall 15b which projects from a peripheral edge of the rectangular plate-like lid portion 15a perpendicularly to this lid portion 15a. Pressing piece portions 15c for holding the inner cases 25 received in the board receiving chambers 17 are formed on an inner surface of the rectangular plate-like lid portion 15a, and extend in the right-left direction. Engagement holes 55 for engagement with the respective retaining projections 11g of the receiving box body 11 are formed respectively on generally central portions (in the right-left direction) of upper and lower portions and generally central portions (in the upward-downward direction) of right and left side portions of the side wall 15b.

Next, a method of assembling the electric circuit board receiving box of the first embodiment will be described. In the electric circuit board receiving box 100 of the first embodiment, the rear lid 15 is fitted on the rear end portion of the receiving box body 11, and the retaining projections 11g of the receiving box body 11 are engaged respectively in the engagement holes 55 of the rear lid 15, thus attaching the rear lid 15 to the receiving box body 11. Then, each inner case 25, receiving the electric circuit board 21 therein, is inserted into the board receiving chamber 17 from the front opening of the receiving box body 11 until the inner case 25 is brought into abutting engagement with the pressing piece portions 15c on the rear lid 15. Thus, the inner cases 15 are received in the board receiving chambers 17, respectively. Then, the lid member 13 is fitted on the front end portion of the receiving box body 11 while fitting the connectors 43 of the connection circuit member 37 respectively into the board connectors 23 of the electric circuit boards 21, and the retaining projection 11f of the receiving box body 11 is engaged in the retaining hole 35 of the lid member 13, thus attaching the lid member 13 to the receiving box body 11.

As a result, each inner case 25 (and hence the electric circuit board 21), received in the board receiving chamber 17, is held between the pressing piece portions 15c of the rear lid 15 and the connector 43 of the connection circuit member 37. At the same time, the front opening of the receiving box body 11 is closed by the lid body 13a (defining the covering surface) of the lid member 13, while the rear opening of the receiving box body 11 is closed by the rear lid 15. With this construction, the mechanical strength of the receiving box body 11, having the front and rear openings, is greatly enhanced. The board connectors 23, mounted respectively on the electric circuit boards 21, are electrically connected to the input/output terminals 39 of the input/output connectors 49 via the electric circuit patterns 53.

In the electric circuit board receiving box 100, the lid member 13 is attached to the receiving box body 11 to cover the opening of the receiving box body 11 in such a manner that the plurality of connectors 43 are collectively fitted at a time into the respective board connectors 23 mounted respectively on the plurality of electric circuit boards 21 received in the receiving box body 11. Therefore, the efficiency of the connecting operation is greatly enhanced. In other words, it is not necessary to carry out a cumbersome connecting operation in which the connectors to be connected together are first found, and then are connected together, and therefore the operation for connecting the connectors together can be easily carried out. And besides, an erroneous connection of the connectors, that is, an erroneous installation, can be positively prevented, and the installation of high reliability can be effected. Furthermore, the lid member 13 for covering the opening of the receiving box body 11 is molded integrally with the connector housings 13f each receiving the input/output terminals 39 for electrical connection to the mating connector 57 of the wire harness 51, and any through hole of a large size for the insertion of the mating connector 57 thereinto does not need to be formed through the lid member 13, and therefore the mechanical strength of the lid member 13 is high. Therefore, the receiving box body 11 is reinforced by the lid member 13 attached thereto.

Furthermore, in the electric circuit board receiving box 100, the input/output terminals 39 (of which connecting relation with the board connectors 23 is suitably adjusted or integrated by the electric circuit patterns 53 formed on the connection circuit member 37), are provided on the connection circuit members 37, and therefore the number of the input/output connectors 49 can be reduced, and merely by connecting the mating connectors 57 of the wire harnesses 51 to the respective input/output connectors, the connection of the plurality of electric circuit boards 21 can be effected positively and easily. And, even if the patterns of the electric circuit board 21 are changed, this change can be easily dealt with by changing the electric circuit patterns 53 of the connection circuit member 37. Furthermore, the female connection terminals 45 of the plurality of connectors 43 are suitably adjusted or integrated by the electric circuit patterns 53 of the connection circuit member 37, and in this condition the female connection terminals 45 are connected to the input/output terminals 39, and therefore a maintenance operation to be effected later can be easily carried out.

### MODIFIED EXAMPLE

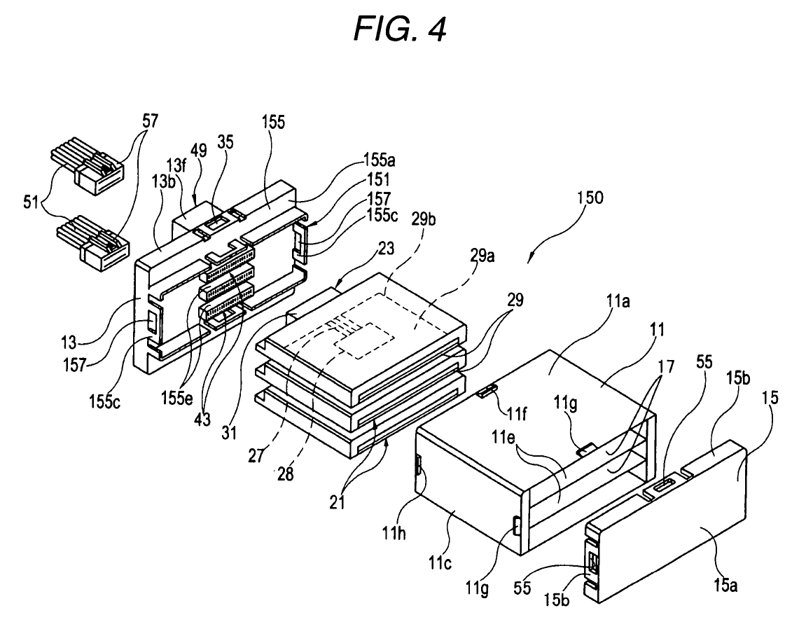

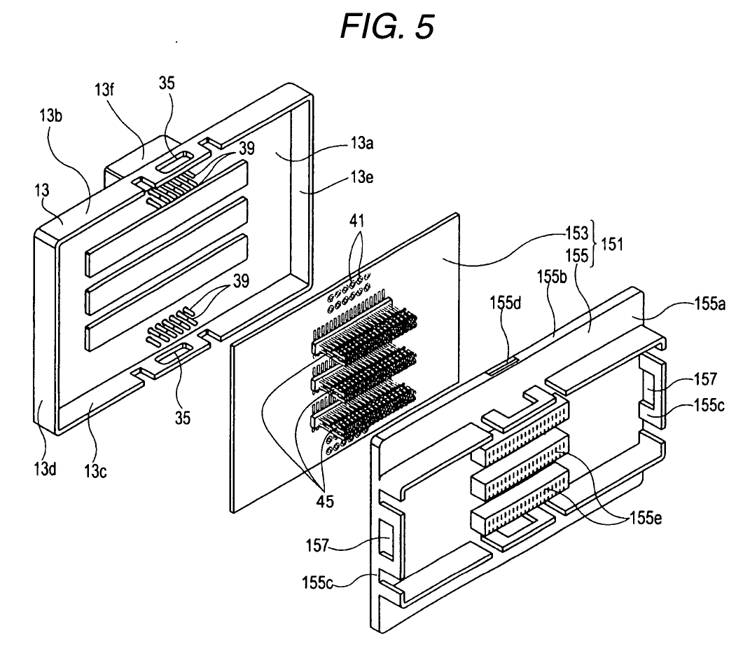

A modified example of the first embodiment of the electric circuit board receiving box of the invention will be described with reference to FIGS. 4 and 5. FIG. 4 is an exploded, perspective view of the modified electric circuit board receiving box, and FIG. 5 is an exploded, perspective view showing a connection circuit member and a lid member of FIG. 4. The modified electric circuit board receiving box differs from the electric circuit board receiving box of the first embodiment only in the connection circuit member, and the other portions are similar, and therefore those portions identical to those of the first embodiment will be designated by identical or corresponding reference numerals, respectively, and explanation thereof will be simplified or omitted.

As shown in FIGS. 4 and 5, the modified electric circuit board receiving box 150 (which is the modified example of the first embodiment) can receive a plurality of electric circuit boards 21 in a stacked manner, and each of the electric circuit boards 21 includes a base board 29 having electric circuit patterns 27 formed thereon, and a board connector 23 which is mounted on the base board 29 to extend along one end edge 29b of this base board 29, and is electrically connected to the electric circuit patterns 27. The electric circuit board receiving box 150 comprises:

a receiving box body 11 which has an opening formed in one side surface thereof, and receives the plurality of electric circuit boards 21 therein in such a manner that the base boards 29 are arranged at intervals, with the board connectors 23 exposed through the opening;

the lid member 13 on which connector housings 13f, each receiving input/output terminals 39 electrically connectable to a mating connector 57 of a wire harness 51, are integrally molded; and

the connection circuit member 151 which is fixed to the lid member 13 so as to be interposed between the lid member 13 and the receiving box body 11, and includes a plurality of connectors 43 fitted respectively to the board connectors 23 to be electrically connected thereto, the connectors 43 being electrically connected to the input/output terminals 39.

The connection circuit member 151 includes an integral housing lid 155 on which connector housings 155e, receiving connection terminals 45 of the plurality of connectors 43, are integrally molded.

The integral housing lid 155 is attached to the receiving box body 11 to cover the opening in the receiving box body 11 in such a manner that the connectors 43 of the connection circuit member 151 are collectively fitted respectively to the board connectors 23 at a time.

The electric circuit board receiving box 150 of this construction will be described below in detail.

The electric circuit board receiving box 150 includes the receiving box 11, the lid member 13, a rear lid 15, and the connection circuit member 151. Retaining projections 11f of a generally triangular cross-section are formed respectively on generally central portions (in an upward-downward direction) of side walls 11c and 11d of the receiving box body 11. The connection circuit member 151 includes a connection board 153, and the integral housing lid 155. The plurality of female connection terminals 45 are mounted on one side (or surface) of the connection board 153 in corresponding relation to the respective board connectors 23 of the electric circuit boards 21. The input/output terminals 39 are mounted at the other side (or surface) of the connection board 153.

The integral housing lid 155 has a generally box-like shape with a closed bottom, and includes a rectangular plate portion 155a, and upper and lower walls (formed on and projecting perpendicularly. respectively from upper and lower portions of the rectangular plate portion 155a), and right and left side walls 155c projecting respectively from right and left side edges of the rectangular plate portion 155a perpendicularly to this plate portion 155a. Retaining projections 155d of a generally triangular cross-section for engagement respectively in retaining holes 35 in the lid member 35 are formed respectively on generally central portions (in a right-left direction) of upper and lower edges 155b and 155b of the rectangular plate portion 155a. Retaining holes 157 for engagement respectively with the retaining projections 11h of the receiving box body 11 are formed respectively through generally central portions (in the upward-downward direction) of the right and left walls 155c. The plurality of connector housings 155e are formed on and project from the rectangular plate portion 155a in corresponding relation to the board connectors 23 of the electric circuit boards 21 received respectively in the board receiving chambers 17. The connection board 153 and the integral housing lid 155 are combined together in such a manner that the female connection terminals 45 of the connection board 153 are received in the connector housings 155e. Thus, the connectors 43, each formed by the connector housing 155e and the female connection terminals 45, are provided at the connection circuit member 151.

In the electric circuit board receiving box 150 of this construction, the integral housing lid 155 of the connection circuit member 151 is attached to the receiving box body 11 to cover the opening of the receiving box body 11 in such a manner that the plurality of connectors 43 of the connection circuit member 151 are collectively fitted at a time into the respective board connectors 23 mounted respectively on the plurality of electric circuit boards 21 received in the receiving box body 11. Therefore, the efficiency of the connecting operation is greatly enhanced as described above for the electric circuit board receiving box 100. In other words, it is not necessary to carry out a cumbersome connecting operation in which the connectors to be connected together are first found, and then are connected together, and therefore the operation for connecting the connectors together can be easily carried out. And besides, an erroneous connection of the connectors, that is, an erroneous installation, can be positively prevented, and the installation of high reliability can be effected. Furthermore, the connector housings 155e, each receiving the connection terminals 45 of the connector 43 (which is to be fitted into the board connector 23 to be electrically connected thereto) are molded integrally on the integral housing lid 155 of the connection circuit member 151, and any through hole of a large size for the insertion of the mating connector 57 thereinto does not need to be formed through the integral housing lid 155, and therefore the mechanical strength of the integral housing lid 155 is high. Therefore, the receiving box body is reinforced by the integral housing lid attached thereto.

Furthermore, since the connector housings 155e of the connectors 43 for connection to the respective board connectors 23 are molded integrally on the integral housing lid 155 of the connection circuit member 151, the relative positional accuracy of the connectors 43 is high, and therefore the connectors 43 can be positively and easily connected respectively to the board connectors 23 of many electric circuit boards 21 stacked together. Preferably, a plurality of connection boards 153, as well as a plurality of integral housing lids 155, which are different in specification from one anther, are prepared, and the optimum connection board 153 and integral housing lid 155 are selected according to the required specification, and are combined together, and by doing so, any one of the various connection circuit members 151 of different specifications can be formed, using the desired connection board 153 and integral housing lid 155 among a minimum number of connection boards 153 and integral housing lids 155.

The other operations and advantageous effects of this modified electric circuit board receiving box 150 will be readily appreciated from the foregoing description of the electric circuit board receiving box 100, and therefore description thereof is omitted here.

### Second Embodiment

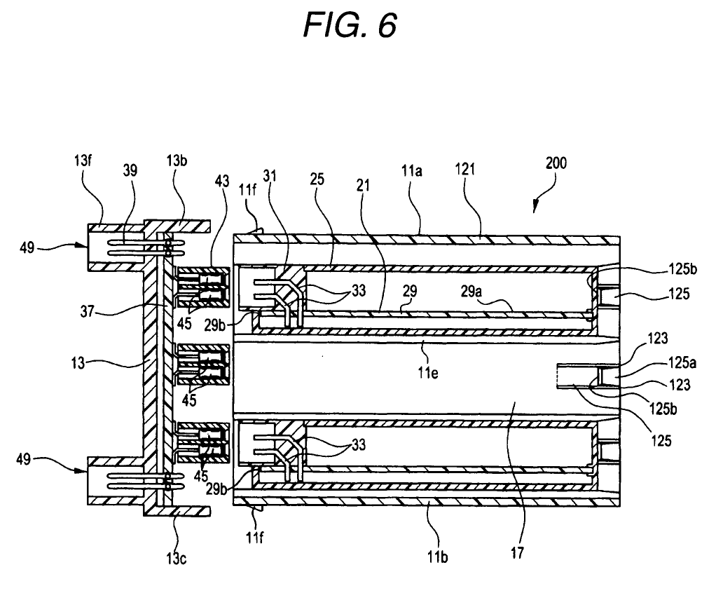

Next, a second embodiment of an electric circuit board receiving box of the invention will be described with reference to FIG. 6. FIG. 6 is a vertical cross-sectional view of the second embodiment of the electric circuit board receiving box of the invention.

As shown in FIG. 6, the electric circuit board receiving box 200 of the second embodiment is similar to the electric circuit board receiving box 100 of the first embodiment except that there is not provided a rear lid and that a receiving box body 121 is partially different from that of the first embodiment. Therefore, those portions identical to those of the first embodiment will be designated by identical or corresponding reference numerals, respectively, and explanation thereof will be simplified or omitted.

Elastic piece portions 125 are formed respectively at rear end portions of right and left side walls 11c and 11d of each of board receiving chambers 17 formed in the receiving box body 121. A pair of parallel slits 123 are formed in each of the right and left side walls 11c and 11d, and extend forwardly from the rear end thereof, thereby forming the elastic piece portion 125 which is separated at its upper and lower edges from the side wall 11c, 11d, and is continuous only at its front end with the side wall 11c, 11d. The elastic piece portion 125 can be elastically deformed in a right-left direction (that is, in a direction perpendicular to the sheet of FIG. 6). The elastic piece portion 125 includes an inclining surface 125a which is formed on an inner surface thereof, and is projecting inwardly gradually from the rear end thereof toward the front end thereof, and a retaining surface 125b extending from the front end of the inclining surface 125a to the inner surface of the elastic piece portion 125 in a direction perpendicular to the side wall 11c, 11d.

When each inner case 25, receiving an electric circuit board 21 therein, is inserted into the corresponding board receiving chamber 17 from the front side, a rear end of the inner case 25 is brought into abutting engagement with the retaining surfaces 125b, so that the inner case 25 is positioned in the forward-rearward direction within the board receiving chamber 17. Alternatively, the inner case 25, receiving the electric circuit board 21 therein, can be inserted into the board receiving chamber 17 through a rear opening thereof, while elastically deforming the pair of elastic piece portions 125. In this case, when the rear end of the inner case 25 reaches the retaining surfaces 125b, the pair of retaining piece portions 125 are restored by their resilient force, so that the retaining surfaces 125b are brought into retaining engagement with the rear end of the inner case 25, thereby preventing rearward withdrawal of the inner case 25.

The other operations and advantageous effects of this embodiment will be readily appreciated from the foregoing description of the electric circuit board receiving box 100 of the first embodiment, and therefore description thereof is omitted here. Also, this is the same with the following embodiments, and therefore such description will be omitted unless otherwise specified.

The above-mentioned modification of FIGS. 4 and 5 (in which the connection circuit member is formed by the connection board and the integral housing lid) can be applied also to the second embodiment and the embodiments to be described hereafter, and such modification can be readily appreciated from the foregoing description, and therefore description thereof will be omitted.

### Third Embodiment

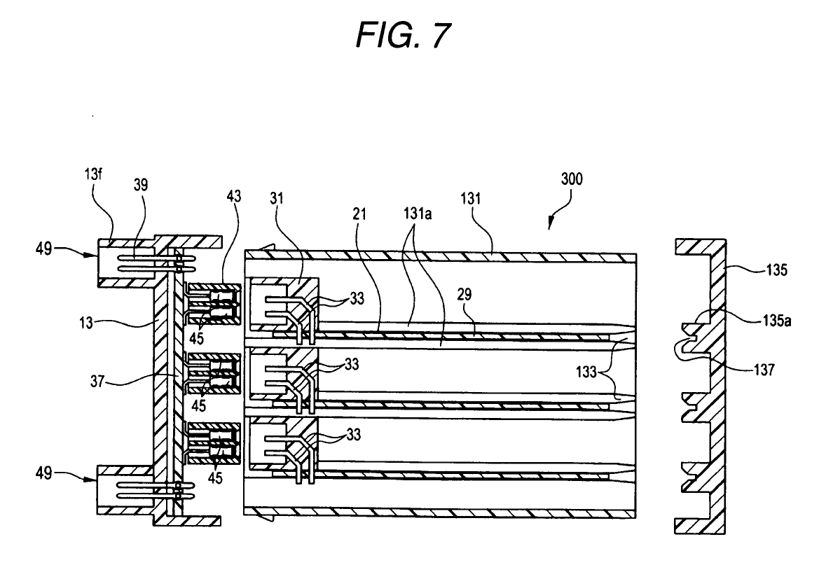

Next, a third embodiment of an electric circuit board receiving box of the invention will be described. FIG. 7 is a vertical cross-sectional view of the third embodiment of the electric circuit board receiving box of the invention.

As shown in FIG. 7, in the electric circuit board receiving box 300 of the third embodiment, any inner case is not used, and electric circuit boards 21 are directly received within a receiving box body 131. A plurality of pairs of ridges 131a are formed on an inner surface of each of right and left side walls 11c and 11d of the receiving box body 131, and extend horizontally. The distance between each pair of ridges 131a is slightly larger than a thickness of the electric circuit board 21, and the pair of ridges 131a form a groove 133 therebetween. The electric circuit board 21 is inserted into the opposed grooves 133, and is received in the receiving box body 131. Holding ribs 135a are formed on an inner surface of a rear lid 135, and extend horizontally in a right-left direction. A groove 137, having a width slightly larger than the thickness of the electric circuit boar 21, is formed in each holding rib 135a, and extends horizontally. The rear end portion of each electric circuit board 21 is inserted into the corresponding groove 137, and by doing so, the rear lid 135 supports the electric circuit boards 21.

The other portions are similar to those of the first embodiment of the electric circuit board receiving box 100 of the invention, and therefore those portions identical to those of the first embodiment are designated by identical or corresponding reference numerals, respectively, and explanation thereof is omitted here.

### Fourth Embodiment

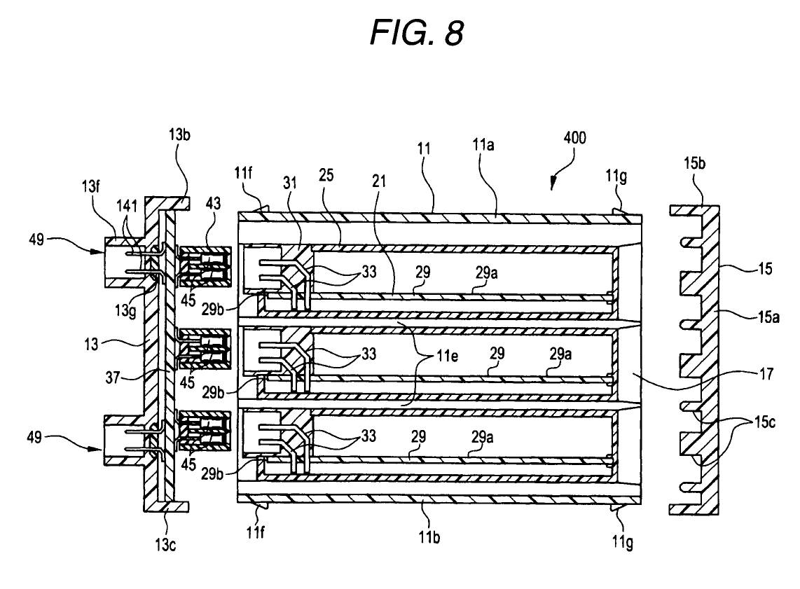

Next, a fourth embodiment of an electric circuit board receiving box of the invention will be described. FIG. 8 is a vertical cross-sectional view of the fourth embodiment of the electric circuit board receiving box of the invention.

The electric circuit board receiving box 400 of the fourth embodiment is similar to the electric circuit board receiving box 100 of the first embodiment (shown in FIG. 3) except that input-output terminals 141 are surface-mounted on the other surface of a connection circuit member 37. The input/output terminals 141 are soldered to electric circuit patterns 53 of the connection circuit member 37 through surface mounting, and each group of input/output terminals 141 pass through respective through holes 13g (formed through a lid member 13), and project into the interior of a corresponding connector housing 13f. Thus, input/output connectors 49 are formed.

### Fifth Embodiment

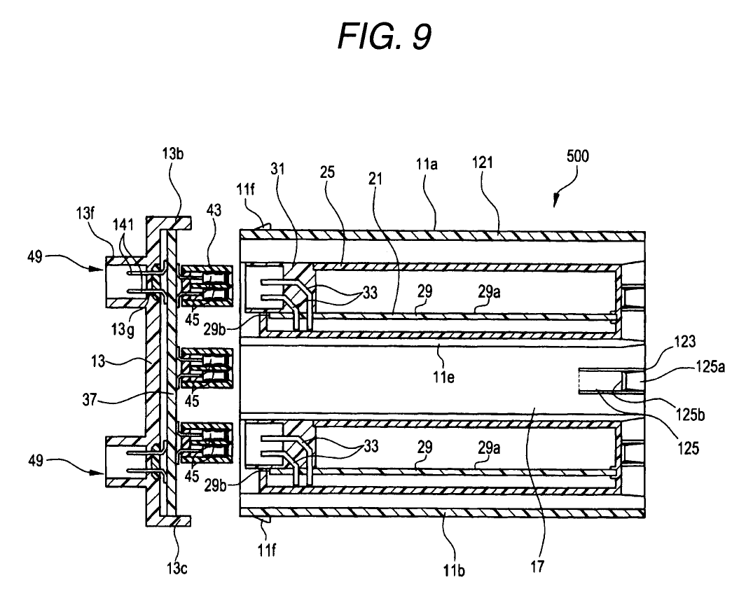

Next, a fifth embodiment of an electric circuit board receiving box of the invention will be described. FIG. 9 is a vertical cross-sectional view of the fifth embodiment of the electric circuit board receiving box of the invention.

The electric circuit board receiving box 500 of the fifth embodiment is similar to the electric circuit board receiving box 200 of the second embodiment (shown in FIG. 6) except that input-output terminals 141 are surface-mounted on the other surface of a connection circuit member 37.

### Sixth Embodiment

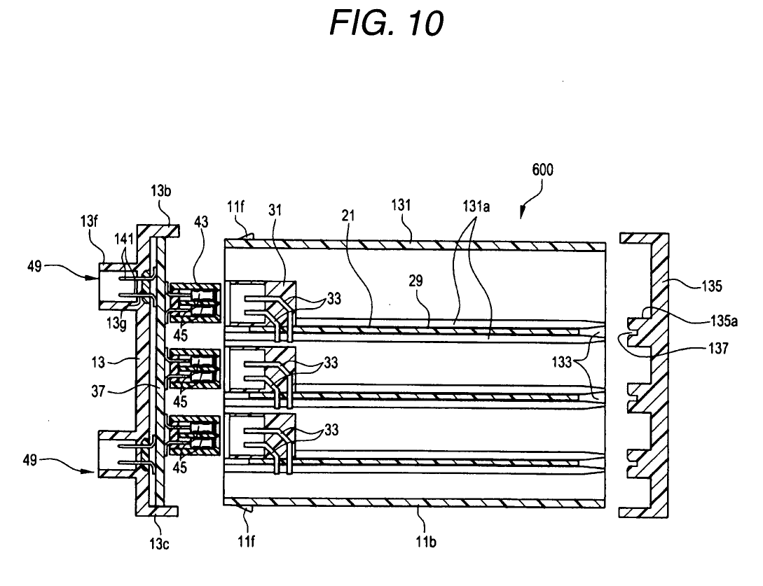

Next, a sixth embodiment of an electric circuit board receiving box of the invention will be described. FIG. 10 is a vertical cross-sectional view of the sixth embodiment of the electric circuit board receiving box of the invention.

The electric circuit board receiving box 600 of the sixth embodiment is similar to the electric circuit board receiving box 300 of the third embodiment (shown in FIG. 7) except that input-output terminals 141 are surface-mounted on the other surface of a connection circuit member 37.

### Seventh Embodiment

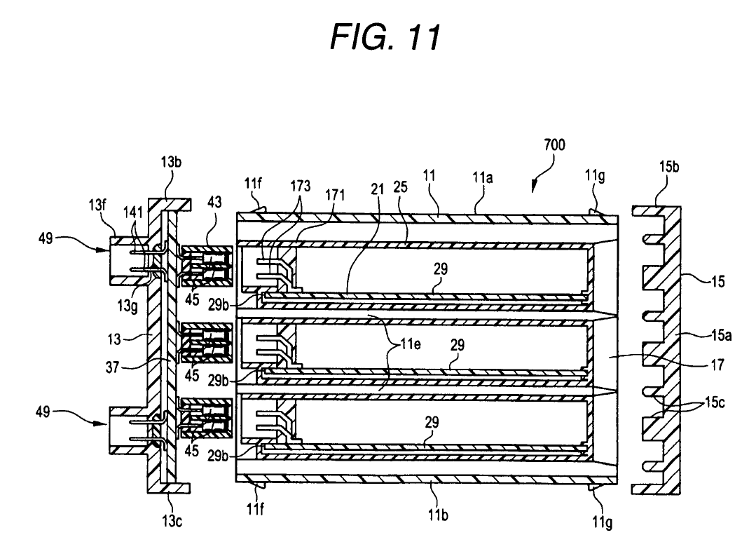

Next, a seventh embodiment of an electric circuit board receiving box of the invention will be described. FIG. 11 is a vertical cross-sectional view of the seventh embodiment of the electric circuit board receiving box of the invention.

The electric circuit board receiving box 700 of the seventh embodiment is similar to the electric circuit board receiving box 400 of the fourth embodiment (shown in FIG. 8) except that a board connector 171, mounted on an electric circuit pattern surface 29a of each electric circuit board 21 to extend along one end edge 29b thereof, is of the surface-mounted type in which male connection terminals 173 are surface-mounted on electric circuit patterns 27 on the electric circuit board 21, and are soldered to the electric circuit patterns 27.

### Eighth Embodiment

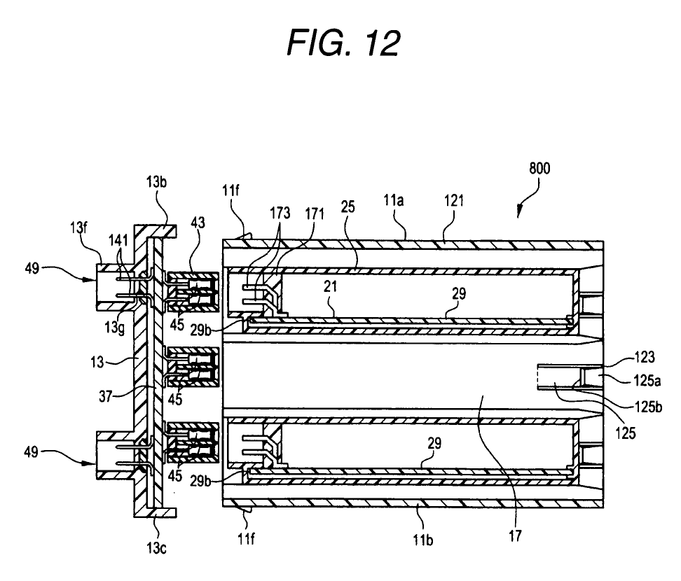

Next, an eighth embodiment of an electric circuit board receiving box of the invention will be described. FIG. 12 is a vertical cross-sectional view of the eighth embodiment of the electric circuit board receiving box of the invention.

The electric circuit board receiving box 800 of the eighth embodiment is similar to the electric circuit board receiving box 500 of the fifth embodiment (shown in FIG. 9) except that a board connector 171, mounted on an electric circuit pattern surface 29a of each electric circuit board 21 to extend along one end edge 29b thereof, is of the surface-mounted type in which male connection terminals 173 are surface-mounted on electric circuit patterns 27 on the electric circuit board 21, and are soldered to the electric circuit patterns 27.

### Ninth Embodiment

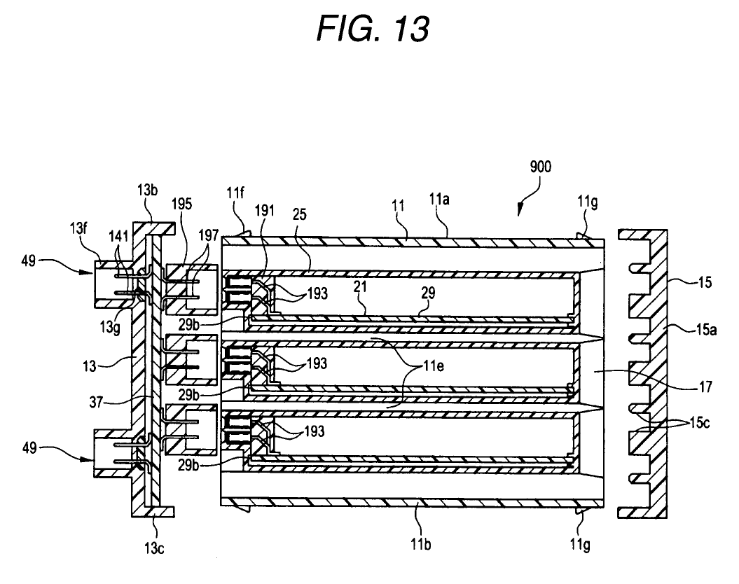

Next, a ninth embodiment of an electric circuit board receiving box of the invention will be described. FIG. 13 is a vertical cross-sectional view of the ninth embodiment of the electric circuit board receiving box of the invention.

In the electric circuit board receiving box 900 of the ninth embodiment, a board connector 191, mounted on each electric circuit board 21 to extend along one end edge 29b thereof, is a male connector, and male connection terminals 193 of the board connector 191 are surface-mounted on electric circuit patterns 27 on the electric circuit board 21. Each connector 195, mounted on one surface of a connection circuit member 37 is a female connector, and male connection terminals 197 of the connector 195 are surface-mounted on the connection circuit member 37. Except the above portions, the electric circuit board receiving box of this embodiment is similar to the electric circuit board receiving box 700 of the seventh embodiment shown in FIG. 11.

### Tenth Embodiment

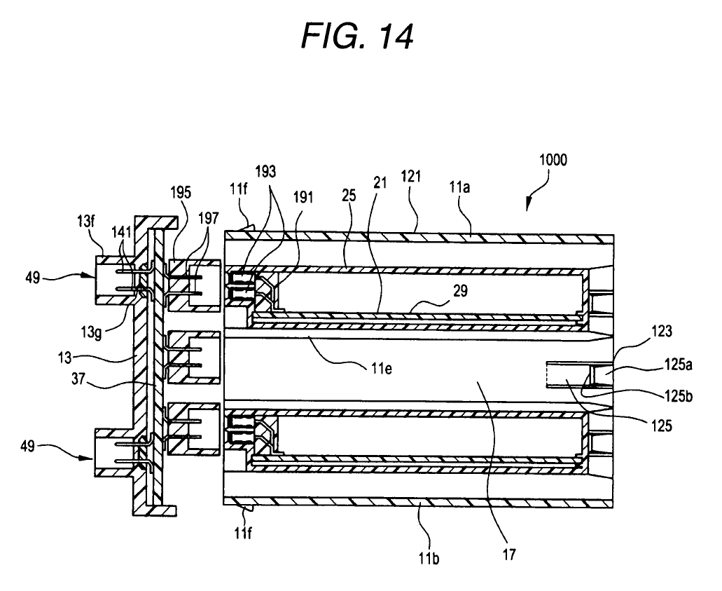

Next, a tenth embodiment of an electric circuit board receiving box of the invention will be described. FIG. 14 is a vertical cross-sectional view of the tenth embodiment of the electric circuit board receiving box of the invention.

The electric circuit board receiving box 1000 of the tenth embodiment is similar to the electric circuit board receiving box 800 of the eighth embodiment (shown in FIG. 12) except that female connection terminals 193 of a male-type board connector 191 are surface-mounted on each electric circuit board 21 and that male connection terminals 197 of each female-type connector 195 are surface-mounted on one surface of a connection circuit member 37.

### Eleventh Embodiment

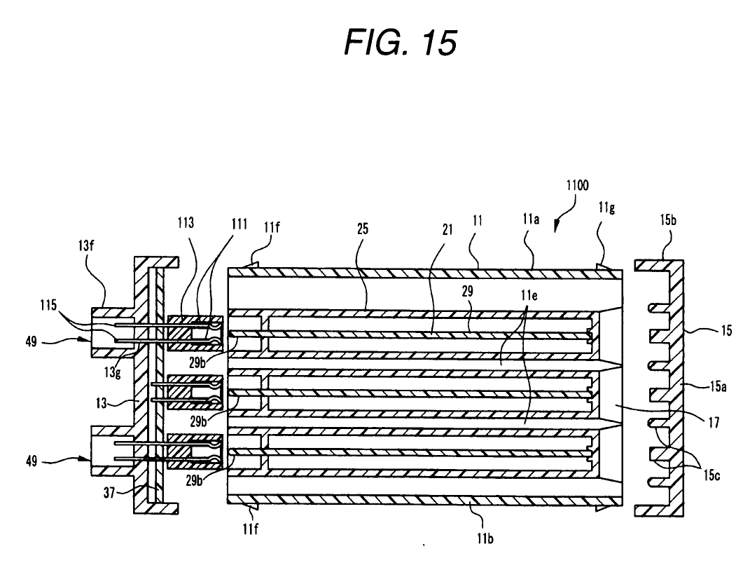

Next, an eleventh embodiment of an electric circuit board receiving box of the invention will be described. FIG. 15 is a vertical cross-sectional view of the eleventh embodiment of the electric circuit board receiving box of the invention.

In the electric circuit board receiving box 1100 of the eleventh embodiment, a board connector is not mounted on each electric circuit board 21, and an electrical contact portion (not shown) is formed on the electric circuit board 21 to extend along one end edge 29b thereof, and is connected to an electric circuit pattern surface 29a. The electrical contact portion may be formed on one side (or surface) of the electric circuit board 21, or may be s formed on both sides (or surfaces) thereof. Each electric circuit board 21 is received within an inner case 25, with its one end edge 29b exposed to the exterior of this inner case 25. Edge connectors 113 are mounted on one side (or surface) of a connection circuit member 37, and connection terminals 111 of each edge connector 113 are resiliently contacted with the electrical contact portion of the corresponding electric circuit board 21, and are electrically connected thereto.

The connection terminals 111 of part of the edge connectors 113 serve also as input/output terminals 115, and the input/output terminals 115 of the edge connector 113 pass respectively through through holes 13g, formed through a lid member 13, and project into the interior of a connector housing 13f, thus forming an input/output connector 49. The connection terminals 111 which do not pass through the through holes 13g in the lid member 13, and contact the electric contact portion of the electric circuit board 21 (that is, the connection terminals 111 provided at the intermediate edge connector 113 in FIG. 15) are suitably adjusted or integrated by electric circuit patterns 53 of the connection circuit member 37, and are connected to the input/output terminals 115 of the input/output connectors 49.

The other portions are similar to those of the electric circuit board receiving box 100 of the first embodiment shown in FIG. 3, and therefore those portions identical to those of the first embodiment are designated by identical or corresponding reference numerals, respectively, and explanation thereof is simplified or omitted here.

### Twelfth Embodiment

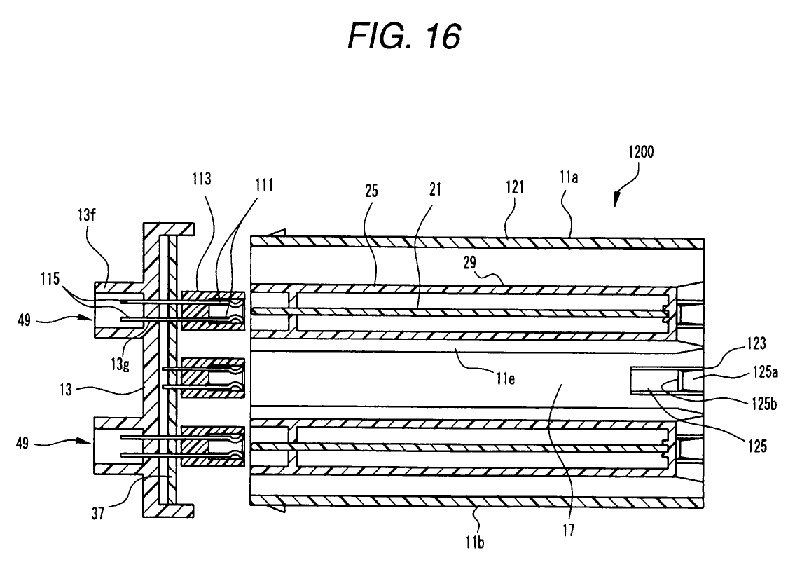

Next, a twelfth embodiment of an electric circuit board receiving box of the invention will be described. FIG. 16 is a vertical cross-sectional view of the twelfth embodiment of the electric circuit board receiving box of the invention.

Like the electric circuit board receiving box 1100 of the eleventh embodiment, the electric circuit board receiving box 1200 of the twelfth embodiment includes electrical contact portions formed respectively on electric circuit boards 21, and edge connectors 113. The other portions are similar to those of the electric circuit board receiving box 200 of the second embodiment shown in FIG. 6, and therefore detailed description thereof is omitted here.

### Thirteenth Embodiment

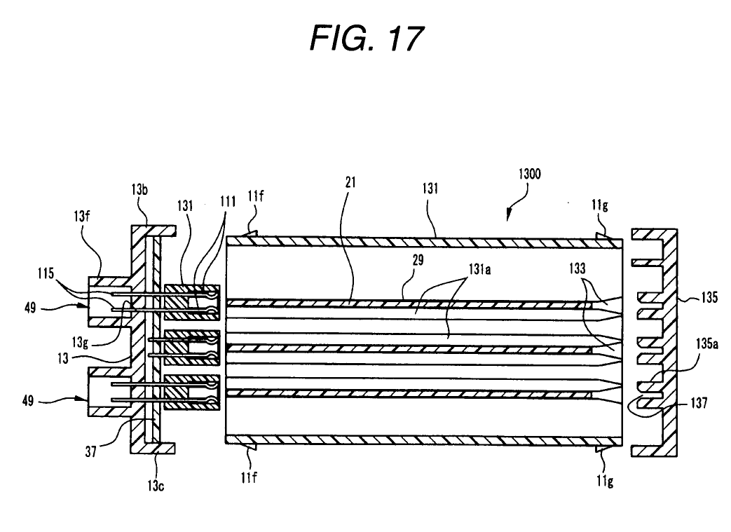

Next, a thirteenth embodiment of an electric circuit board receiving box of the invention will be described. FIG. 17 is a vertical cross-sectional view of the thirteenth embodiment of the electric circuit board receiving box of the invention.

Like the electric circuit board receiving box 1100 of the eleventh embodiment, the electric circuit board receiving box 1300 of the thirteenth embodiment includes electrical contact portions formed respectively on electric circuit boards 21, and edge connectors 113. The other portions are similar to those of the electric circuit board receiving box 300 of the third embodiment shown in FIG. 7, and therefore detailed description thereof is omitted here.

The present invention is not limited to the above embodiments and modification, and suitable changes, improvement and so on can be made. The material, shape, dimensions, numeral value, form, number, disposition, etc., of each of the constituent elements of the above embodiments and modification are arbitrary, and are not limited in so far as the invention can be achieved.

The present application is based on Japan Patent Application No. 2005-083952 filed on Mar. 23, 2005, the contents of which are incorporated herein for reference.

What is claimed is:

1. A receiving box for receiving a plurality of electric circuit boards having board connectors respectively, comprising:
a receiving box body that is configured to receive the electric circuit boards therein, and has an opening for exposing the board connectors therethrough;
a lid member that has a connector for connecting to a mating connector of a wire harness; and
a connection circuit member that has a plurality of connectors for electrically connecting to the board connectors of the electric circuit boards, and is mounted on the lid member so as to electrically connect the connector of the lid member to the connectors of the connection circuit member,
wherein when the lid member is attached to the receiving box body to cover the opening in the receiving box body, the connectors of the connection circuit member are collectively fitted to the board connectors respectively.

2. The receiving box as set forth in claim 1, wherein the lid member has a first engagement portion; and
wherein the receiving box body has a second engagement portion that engages to the first engagement portion of the lid member.

3. The receiving box as set forth in claim 1, wherein the connection circuit member is interposed between the lid member and the receiving box body.

4. The receiving box as set forth in claim 1, wherein the electric circuit boards are arranged at intervals in a stacked manner.

5. A receiving box for receiving a plurality of electric circuit boards having board connectors respectively, comprising:
a receiving box body that is configured to receive the electric circuit boards therein, and has an opening for exposing the board connectors therethrough;
a lid member that has a connector for connecting to a mating connector of a wire harness;
a connection circuit member that has a plurality of connecting terminals for electrically connecting to the board connectors of the electric circuit boards, and is configured to electrically connect the connector of the lid member to the connectors of the connection circuit member; and
a housing lid member that has a plurality of housings for receiving the connecting terminals to form a plurality of connectors of the connection circuit member,
wherein when the lid housing member is attached to the receiving box body to cover the opening in the receiving box body, the connectors of the connection circuit member are collectively fitted to the board connectors respectively.

6. The receiving box as set forth in claim 5, wherein the lid housing member has a first engagement portion; and
wherein the receiving box body has a second engagement portion that engages to the first engagement portion of the lid housing member.

7. The receiving box as set forth in claim 5, wherein the lid member has a third engagement portion; and
wherein the lid housing member has a fourth engagement portion that engages to the third engagement portion of the lid member.

8. The receiving box as set forth in claim 5, wherein the connection circuit member is interposed between the lid member and the lid housing member.

9. The receiving box as set forth in claim 5, wherein the electric circuit boards are arranged at intervals in a stacked manner.
